(19) United States
(12) Patent Application Publication
(10) Pub. No.: US 2013/0140156 A1
(43) Pub. Date: Jun. 6, 2013

(54) PIEZOELECTRIC ACTUATOR AND METHOD FOR MANUFACTURING SAME

(71) Applicant: Taiyo Yuden Co., Ltd., Tokyo (JP)

(72) Inventors: Tomonori FUJII, Tokyo (JP); Takayuki TAKANO, Tokyo (JP)

(73) Assignee: TAIYO YUDEN CO., LTD., Tokyo (JP)

(21) Appl. No.: 13/691,111

(22) Filed: Nov. 30, 2012

(30) Foreign Application Priority Data
Dec. 2, 2011 (JP) 2011-264202

(51) Int. Cl. H01L 41/083; H01H 57/00; H01L 41/29; H01L 41/047

(52) U.S. Cl. CPC H01L 41/0838; H01L 41/0478; H01H 57/00; H01L 41/29
USPC 200/181; 310/363; 310/364; 29/25.35

(57) ABSTRACT

A piezoelectric actuator according to an embodiment of the present invention includes a base substrate provided with cantilevers and a piezoelectric element formed on each cantilever. The piezoelectric element includes: a lower electrode layer; a piezoelectric layer formed on the lower electrode layer; and an upper electrode layer having a conductive oxide layer formed on the piezoelectric layer. Because the conductive oxide layer has covalent bonds or ionic bonds, and therefore produces little plastic deformation, relaxation of the stress is less likely to occur. Thus, even with repetitive motion in the piezoelectric actuator, the as-deposited internal stress (film stress) can be stably maintained for a long period of time.

This application claims the benefit of Japanese Application No. 2011-264202, filed in Japan on Dec. 2, 2011, which is hereby incorporated by reference in its entirety.

### BACKGROUND OF THE INVENTION

1. Field of the Invention

The present invention relates to a piezoelectric actuator that uses a piezoelectric element as an actuating part thereof, and to a method of manufacturing same.

2. Description of Related Art

An MEMS (Micro Electro Mechanical System) switch, a variable capacitor, a variable filter obtained by combining the two, and the like are known as actuators provided with a cantilever that is actuated by a piezoelectric element, for example. Patent Document 1 below, for example, describes a piezoelectric MEMS switch. In a piezoelectric MEMS switch, the higher the piezoelectric constant that is one of the material properties becomes, the lower the actuation voltage can be. Therefore, when using PZT, which is a typical piezoelectric material, for example, film deposition and recrystallization processes are performed at a high temperature so as to achieve the perovskite crystal structure that has a high piezoelectric property. While these high-temperature film deposition and recrystallization processes contribute to an improvement in the characteristics of the piezoelectric material, as a result of these processes, the internal stress is changed due to mismatch of linear expansion coefficient with a lower electrode and the like, thereby causing the cantilever to be deformed (warped).

To address this problem, Patent Document 2 below, for example, discloses a configuration in which a fixing part of a substrate that holds one end of a cantilever has a triangular recess so as to suppress the warping of the cantilever. Further, Non-Patent Document 1 below discloses a method of forming a Ta film that has strong compressive stress on a Pt film that is an upper electrode of a piezoelectric cantilever so as to control the warping of the cantilever.

Patent Document 3 below discloses a configuration for obtaining the perovskite crystal structure that has a high piezoelectric property. In the configuration, a lower electrode layer is constituted of a conductive oxide that is mainly made of lanthanum nickelate, and a piezoelectric layer is constituted of a perovskite oxide ferroelectric material that is mainly made of lead zirconate titanate deposited by the liquid phase epitaxy method.

### RELATED ART DOCUMENTS

### Patent Documents

Patent Document 1: Japanese Patent Application Laid-Open Publication No. 2010-177143
Patent Document 2: Japanese Patent Application Laid-Open Publication No. H6-273160
Patent Document 3: Japanese Patent Application Laid-Open Publication No. 2009-54934

### Non-Patent Document

Non-Patent Document 1: Ryuichi Kondou, et al., “Stress control for PZT actuated cantilever”, the 67^{th} Japan Society of Applied Physics Annual Technical Meeting Proceedings, 67, 2, p. 524, published on Aug. 29, 2006

### SUMMARY OF THE INVENTION

In the method disclosed in Non-Patent Document 1 above, a metal layer is provided for controlling the stress of the piezoelectric element. In such a configuration, relaxation of internal stress of the metal layer occurs due to plastic deformation or creep of the metal layer, which is caused by repetitive motion, and as a result, the stress control amount that was initially set may be changed, causing the cantilever to warp. Consequently, in the case of the piezoelectric MEMS switch, a distance between a moveable terminal connected to the cantilever and a fixed terminal (signal line) that faces the moveable terminal changes due to repetitive motion, and as a result, a switch actuation voltage to establish the ON state is caused to change.

In view of the above-mentioned situations, an object of the present invention is to provide a piezoelectric actuator that can stably maintain an internal stress of a piezoelectric element and a method of manufacturing the same.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, a piezoelectric actuator according to an embodiment of the present invention includes a base substrate and a piezoelectric element.

The base substrate includes a base and a cantilever that has a first end portion fixed to the base.

The piezoelectric element can elastically deform the cantilever, and includes a first electrode formed on the cantilever, a piezoelectric layer formed on the first electrode, and a second electrode that includes a first conductive oxide layer formed on the piezoelectric layer.

A method of manufacturing a piezoelectric actuator according to an embodiment of the present invention includes: forming a first electrode on a base substrate in a region where a cantilever is to be formed.

On the first electrode, a piezoelectric layer is formed of a material that has an in-plane tensile stress.

On the piezoelectric layer, a second electrode that includes a conductive oxide layer that has an in-plane compressive stress is formed.

By etching the base substrate, the cantilever is formed.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is a schematic plan view showing a configuration of a piezoelectric actuator according to Embodiment 1 of the present invention.

FIG. 2 is a cross-sectional view along the line A1-A1 in FIG. 1.

FIG. 3 is a cross-sectional view along the line A2-A2 in FIG. 1.

FIG. 4 is a cross-sectional view for illustrating a mechanism of the piezoelectric actuator.

FIG. 5 is a schematic cross-sectional view showing a configuration of a piezoelectric element used in the piezoelectric actuator.

FIG. 6 is a schematic diagram showing the direction of the internal stress of each layer of the piezoelectric element in the in-plane direction.

FIGS. 7A through 7C are cross-sectional views of a main part in respective processes for illustrating a structure of the piezoelectric actuator and a manufacturing method thereof.

FIGS. 8A through 8C are cross-sectional views of a main part in respective processes for illustrating a structure of the piezoelectric actuator and a manufacturing method thereof.

FIGS. 9A and 9B are cross-sectional views of a main part in respective processes for illustrating a structure of the piezoelectric actuator and a manufacturing method thereof.

FIG. 10 is a graph showing a relationship between a metal layer and a conductive oxide layer that constitute an upper electrode layer of the piezoelectric element.

FIG. 11 is a schematic cross-sectional view showing a configuration of a piezoelectric element according to Embodiment 2 of the present invention.

### DETAILED DESCRIPTION OF THE PREFERRED EMBODIMENTS

A piezoelectric actuator according to an embodiment of the present invention is provided with a base substrate and a piezoelectric element. The base substrate includes a base and a cantilever that has a first end portion fixed to the base. The piezoelectric element can elastically deform the cantilever, and includes a first electrode formed on the cantilever, a piezoelectric layer formed on the first electrode, and a second electrode that has a first conductive oxide layer formed on the piezoelectric layer.

In the piezoelectric actuator, the second electrode formed on the piezoelectric layer includes a conductive oxide layer. Because the conductive oxide is not formed by metallic bonding, and therefore produces little plastic deformation, relaxation of the stress is less likely to occur. Thus, even with the repetitive motion in the piezoelectric actuator, the as-deposited internal stress (film stress) can be stably maintained for a long period of time. Also, because it conducts electricity, the voltage applied to the piezoelectric element is not divided, which makes it possible to suppress a change in the actuation voltage of the piezoelectric element.

The internal stress of the first conductive oxide layer is set such that the curvature of the cantilever after the element is completed comes within a prescribed range. The internal stress of the first conductive oxide layer can be adjusted by the film thickness, film forming conditions, and the like. The internal stress of the first conductive oxide layer can be appropriately set in accordance with the size of the internal stress of the piezoelectric layer, the length of the cantilever, the allowable curvature of the cantilever, and the like.

The material of the first conductive oxide layer can be selected according to the direction of the internal stress of the piezoelectric layer (tensile or compressive). For example, when the piezoelectric layer is formed of a material that has an in-plane tensile stress, the first conductive oxide layer is formed of a material that has an in-plane compressive stress. This way, the internal stress of the piezoelectric layer is reduced, and deformation or warping of the cantilever can be prevented.

As the piezoelectric material that has an in-plane tensile stress, lead zirconate titanate (PZT) can be used, for example. As a conductive oxide that has an in-plane compressive stress, lanthanum nickelate (LNO:LaNiO₃) can be used, for example. LNO has the perovskite crystal structure, and the lattice constant thereof is 3.84 \acute{Å}, which is close to the lattice constant of PZT (4.01 \acute{Å}). Therefore, it is possible to form an interface structure that causes little distortion between the conductive oxide layer and the piezoelectric layer.

In this case, the second electrode may further include a metal layer that has an in-plane tensile stress on the first conductive oxide layer. When the second electrode has a multi-layer structure of the first conductive oxide layer and the metal layer in the manner described above, it is possible to achieve the optimum stress design by appropriately setting the thickness and the film forming conditions of each layer.

A Pt/Ti film can be used as the metal layer, for example. The Ti film is provided as an adhesion layer. These metal films are typically deposited by sputtering, and the direction of the internal stress varies depending on the film forming temperature. For example, when the Pt film is formed at room temperature, the resultant film exhibits an in-plane compressive stress, and when the Pt film is formed at a temperature of 200° C. or higher, for example, the resultant film exhibits an in-plane tensile stress.

The first electrode may include a second conductive oxide layer that has an in-plane compressive stress. The second conductive oxide layer can be made of LNO having the perovskite structure, for example. By using this layer as an underlying layer of the piezoelectric layer made of PZT, the orientation in the piezoelectric layer can be improved, thereby achieving an excellent piezoelectric characteristic.

The piezoelectric actuator may further include a moveable terminal and a signal line. The moveable terminal is connected to a second end portion of the cantilever. The signal line is connected to the base, and has a fixed terminal that can make contact with the moveable terminal when the cantilever is actuated by the piezoelectric element and deformed.

With such a piezoelectric actuator, it is possible to prevent a change in a space between the moveable terminal and the fixed terminal caused by repetitive motion. This prevents a change in the switch actuation voltage, making it possible to maintain a reliable switching operation for a long period of time.

A method of manufacturing a piezoelectric actuator according to an embodiment of the present invention includes forming a first electrode on a base substrate in a region where a cantilever is to be formed.

On the first electrode, a piezoelectric layer is formed of a material that has an in-plane tensile stress.

On the piezoelectric layer, a second electrode is formed. The second electrode includes a conductive oxide layer that has an in-plane compressive stress.

By etching the base substrate, the cantilever is formed.

According to this manufacturing method, the internal stress of the piezoelectric layer can be reduced by the conductive oxide layer, and therefore, it is possible to prevent deformation or warping of the cantilever. Particularly, because the conductive oxide is not formed by metallic bonding, and therefore produces little plastic deformation, relaxation of the stress is less likely to occur. Thus, even with the repetitive motion in the piezoelectric actuator, the as-deposited internal stress (film stress) can be stably maintained for a long period of time. Also, because the second electrode that constitutes the uppermost layer of the piezoelectric element is provided with the above-mentioned stress control function, it is possible to adjust the internal stress of the piezoelectric element near the final step of the manufacturing process.

The step of forming the second electrode may include: forming the conductive oxide layer on the piezoelectric layer; and forming a metal layer that has an in-plane tensile stress on the conductive oxide layer. This makes it possible to optimize the stress design by appropriately setting the thickness and the film forming conditions of each layer in the second electrode.

The film forming temperature of the metal layer may be set to 200° C. or higher. This way, the internal stress of the metal layer can be controlled so as to exhibit an in-plane tensile stress. Also, by setting the film forming temperature of the metal layer to 200° C. or higher, it is possible to prevent the internal stress from being relaxed during a process of mounting the piezoelectric actuator by reflow soldering, for example.

Below, with reference to figures, embodiments of the present invention will be explained. In the embodiments below, an example in which the piezoelectric actuator is used as a piezoelectric MEMS switch will be explained. The piezoelectric MEMS switch is provided in a wireless communication device such as a mobile phone, for example, for switching the state of high-frequency signal between a transmission state and an open state.

In the embodiments below, specific numeral values are provided for describing configurations of respective members, but these values are merely examples, and not limiting. For ease of explanation, the ratios of sizes and thicknesses of respective members shown in figures do not represent actual ratios.

### Embodiment 1

(Configuration of Piezoelectric Actuator)

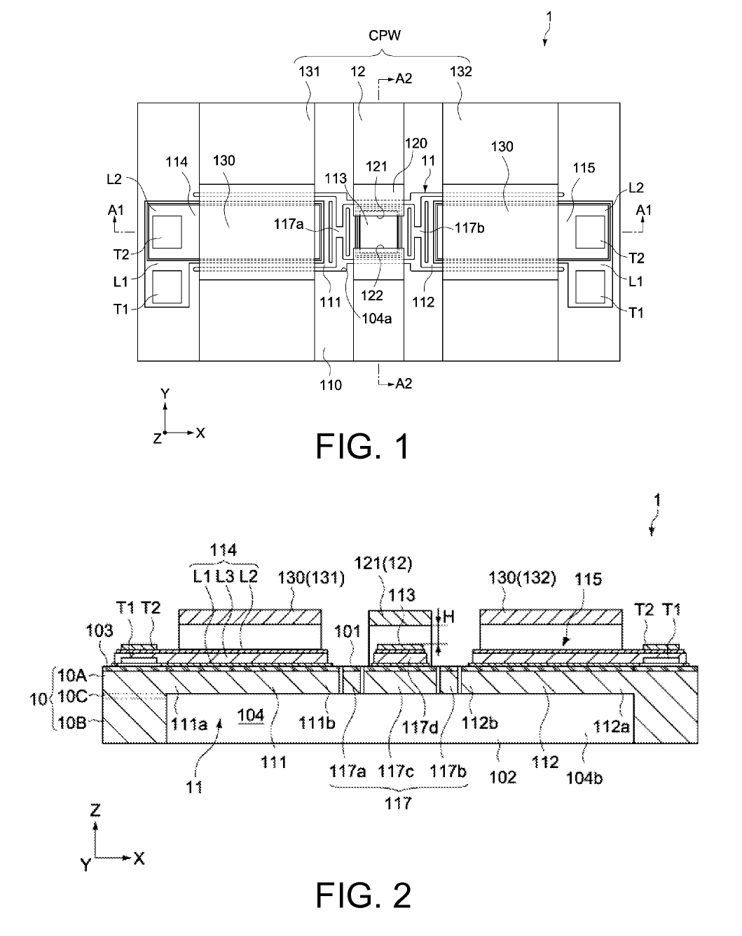

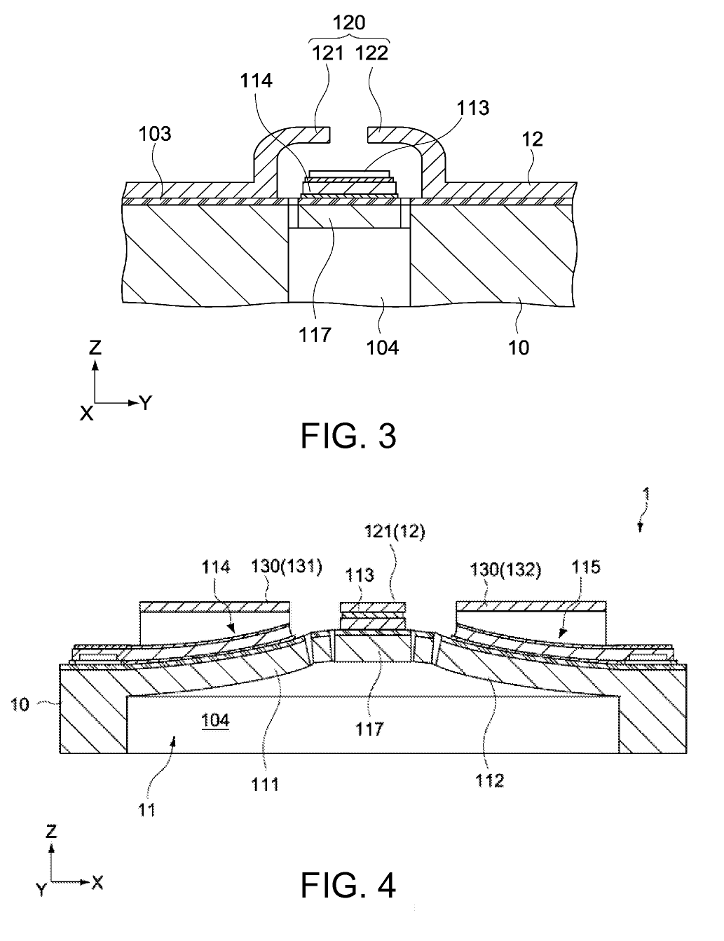

FIGS. 1 to 4 schematically show a configuration of a piezoelectric actuator according to Embodiment 1 of the present invention. FIG. 1 is a plan view of the piezoelectric actuator. FIG. 2 is a cross-sectional view along the line A1-A1 in FIG. 1. FIG. 3 is a cross-sectional view along the line A2-A2 in FIG. 1. FIG. 4 is a cross-sectional view showing an example of the mechanism of the piezoelectric actuator. In each figure, X axis and Y axis directions represent horizontal directions orthogonal to each other. Z axis represents a height direction orthogonal to the X axis and Y axis. In this embodiment, the piezoelectric actuator is constructed as a piezoelectric MEMS switch (piezoelectric switch).

The piezoelectric actuator 1 of this embodiment includes a base substrate 10, a moveable part 11, a signal line 12, and a pair of ground lines 131, 132.

The moveable part 11 has a first cantilever 111, a second cantilever 112, a moveable terminal 113, a first piezoelectric actuating part 114, and a second piezoelectric actuating part 115. As described below, the piezoelectric actuator 1 has a function of switching between a state in which the moveable terminal 113 and the signal line 12 are separated (FIG. 2) and a state in which the movable terminal 113 and the signal line 12 are in contact (FIG. 4).

The base substrate 10 includes a base 110 and first and second cantilevers 111, 112 that have respective one ends fixed to the base 110. The base substrate 10 is made of a single-crystal silicon substrate (elastic layer) having a front surface 101 and a rear surface 102 parallel to X axis and Y axis. The front surface 101 of the base substrate 10 is covered by an insulating film 103 made of a thermal oxide film (silicon oxide film), for example. The base 110 has an opening 104 that houses the moveable part 11.

The first cantilever 111 and the second cantilever 112 are respectively extended in the X axis direction, and are made of a material that can be elastically deformed. In this embodiment, they are made of single-crystal silicon. The first and second cantilevers 111, 112 have the same length (X axis direction), width (Y axis direction), and thickness (Z axis direction), and are disposed on the same plane in the opening 104 so as to face each other in the X axis direction. Respective one ends 111a, 112a of the cantilevers 111, 112 are fixed to the periphery of the opening 104, and the other ends 111b, 112b face each other in the X axis direction.

There is no special limitation on the length, width, or thickness of the first and second cantilevers 111, 112, and the respective cantilevers can be set to be 50 to 750 μm in length, 20 to 400 μm in width, and 2 to 10 μm in thickness, for example. In this embodiment, the length, width, and thickness thereof are respectively set to 550 μm, 200 μm, and 5 μm.

Between the first cantilever 111 and the second cantilever 112, a supporting member 117 that supports the moveable terminal 113 is provided. The supporting member 117 is formed to be coplanar with the first cantilever 111 and the second cantilever 112, and includes a first connecting part 117a, a second connecting part 117b, a supporting part 117c, and a middle layer 117d. The first connecting part 117a, the second connecting part 117b, and the supporting part 117c are formed to be coplanar with the first and second cantilevers 111, 112, and have the same thickness as that of those cantilevers.

The first connecting part 117a is connected to the end 111b of the first cantilever 111, and has a hinge structure allowing for an elastic deformation. The second connecting part 117b is connected to the end 112b of the second cantilever 112, and has a hinge structure allowing for an elastic deformation. The supporting part 117c is connected to the first and second cantilevers 111, 112, respectively, through the first and second connecting parts 117a, 117b, and has a supporting surface that supports the moveable terminal 113 through the insulating film 103 and the middle layer 117d. There is no special limitation on the shape of the first and second connecting parts 117a, 117b as long as they are formed in an appropriate shape that allows the supporting part 117c to move so as to follow the first and second cantilevers 111, 112.

The middle layer 117d may be a conductor, or may be an insulator. The middle layer 117d may be formed of constituting materials of respective function layers (conductive layer, dielectric layer) formed on the front surface 101 of the base substrate 10. The structure of the middle layer 117d is not limited to a single layer structure, and may be a multi-layer structure. The thickness of the middle layer 117d is not limited to a specific value, and can be appropriately set in accordance to the size of a space between the moveable terminal 113 and a fixed terminal 120 in the switch OFF state (corresponding to the height H).

In this embodiment, the middle layer 117d has the same multi-layer structure as that of first and second piezoelectric actuating parts 114, 115, which will be described below. In this case, the middle layer 117d is formed simultaneously with the first and second piezoelectric actuating parts 114, 115. This eliminates a need to add a separate step for forming the middle layer 117d, and therefore, a decrease in productivity due to an increased number of process steps can be prevented. The middle layer 117d is not electrically connected to the first and second piezoelectric actuating parts 114, 115, and is separately formed on the supporting part 117c. Therefore, upon actuating the first and second piezoelectric actuating parts 114, 115, the middle layer 117d is not deformed, thereby ensuring a stable contact state between the moveable terminal 113 and the fixed terminal 120.

The moveable terminal 113 is made of a conductive material, which typically is a metal material, but may also be formed of a non-metal material such as a conductive oxide or the like. In this embodiment, the moveable terminal 113 is made of a Ti (titanium) film as an adhesion layer and a Pt (platinum) film as an electrode layer deposited thereon. A pure Pt film has advantages of a high degree of hardness and relatively easy film deposition that allows for excellent productivity. The electrode layer may be formed of a Pt/Ir alloy (with an Ir content of 10 at % or less, for example). This makes it possible to form a moveable terminal that has a high degree of hardness and excellent wear resistance. Alternatively, the electrode layer may be formed of an Au material such as pure Au or an Au alloy, instead of a Pt material. Because pure Au has a low resistance, the contact resistance with the signal line 12 can be reduced. Examples of the Au alloy include an Au/Ni alloy (with an Ni content of Sat % or less, for example) and an Au/Ag alloy (with an Ag content of 40 at % or less, for example). The Au/Ni alloy has a high degree of hardness and excellent wear resistance. The Au/Ag alloy has an advantage of a low resistance. The adhesion layer may be made of TiW, TiN, TiO, Cr, or the like, instead of Ti. The moveable terminal 113 is formed above the supporting part 117c through the insulating film 103 and the middle layer 117d. The thickness thereof is not limited to a specific value, and is set to 0.2 μm, for example.

The base substrate 10 may be formed of a single layer silicon substrate, but in this embodiment, an SOI (Silicon On Insulator) substrate having a multi-layer structure of a first silicon substrate 10A and a second silicon substrate 10B is used.

The first silicon substrate 10A is formed to have the same thickness as that of the first and second cantilevers 111, 112. The thickness of the first silicon substrate 10A is not limited to a specific value, and can be set in a range of 2 μm to 10 μm, for example. In this embodiment, the thickness is set to 5 μm. The thickness of the second silicon substrate 10B accounts for a large part of the thickness of the base substrate 10, and is set so as to allow good handling of the substrate. The thickness of the second silicon substrate 10B is not limited to a specific value, and can be set in a range of 100 μm to 750 μm, for example. In this embodiment, the thickness is set to 500 μm. The first silicon substrate 10A and the second silicon substrate 10B are bonded to each other through a bonding layer 10C. The bonding layer 10C is made of a silicon oxide film, for example.

The first cantilever 111, the second cantilever 112, and the supporting member 117 are formed by patterning the first silicon substrate 10A. As described later, in this embodiment, by forming a resist pattern on the surface of the first silicon substrate 10A, and performing dry-etching or wet-etching using the resist pattern as a mask, the first cantilever 111, the second cantilever 112, and the supporting member 117 are respectively formed in the first silicon substrate 10A. Therefore, the respective surfaces of the first cantilever 111, the second cantilever 112, and the supporting member 117 are formed to be flush with the front surface 101 of the base substrate 10.

The opening 104 is made of a slit 104a (FIG. 1) that is formed in the above-mentioned etching process and that penetrates the first silicon substrate 10A and a recess 104b (FIG. 2) that is formed in the second silicon substrate 10B. The recess 104b is formed by performing dry-etching or wet-etching to the second silicon substrate 10B. The recess 104b is formed to be large enough to allow the moveable part 11 to be exposed when viewed from a side of the rear surface 102 of the base substrate 10. This makes it possible to allow the moveable part 11 to deform inside the opening 104 in the Z-axis direction.

The first piezoelectric actuating part 114 and the second piezoelectric actuating part 115 are formed on the front surface 101 of the base substrate 10 through the insulating film 103. The first and second piezoelectric actuating parts 114, 115 have the same structure, and as shown in FIG. 2, are made of a multi-layer film of a lower electrode layer L1, an upper electrode layer L2, and a piezoelectric layer L3 formed between the lower electrode layer L1 and the upper electrode layer L2.

The first and second piezoelectric actuating parts 114, 115 are formed in a substantially rectangular shape that is longer in the X axis direction on the respective surfaces of the first cantilever 111 and the second cantilever 112. In the first and second piezoelectric actuating parts 114, 115, a prescribed voltage is applied between the lower electrode layer L1 and the upper electrode layer L2 so as to cause the piezoelectric layer L3 to contract, thereby making the first and second cantilevers 111, 112 deform in the Z axis direction. As described above, the first and second piezoelectric actuating parts 114, 115 are configured so as to switch between a first state, in which the moveable terminal 113 is in contact with the signal line 12 (switch ON state, in this example), and a second state, in which the moveable terminal 113 and the signal line 12 are separated (switch OFF state, in this example).

The first and second piezoelectric actuating parts 114, 115 are actuated in a synchronized manner. For example, the second piezoelectric actuating part 115 is configured so as to move the supporting member 117 (moveable terminal 113) in the Z axis direction in synchronization with the first piezoelectric actuating part 114. Typically, in the switch ON state, the first and second piezoelectric actuating parts 114, 115 are supplied with an actuation voltage at the same time, and in the switch OFF state, the supply of the actuation voltage to the first and second piezoelectric actuating parts 114, 115 is stopped at the same time.

The first and second piezoelectric actuating parts 114, 115 may be formed on the respective rear surfaces of the first and second cantilevers 111, 112. In this case, by applying a voltage to the respective electrode layers so as to cause the piezoelectric layer to expand, the respective cantilevers 111, 112 can be deformed.

The lower electrode layer L1 and the upper electrode layer L2 respectively have terminal layers T1, T2 that are connected to a not-shown driver circuit. The driver circuit is typically constituted of a DC circuit, but may be constituted of a pulse oscillator circuit. One of the lower electrode layer L1 and the upper electrode layer L2 is connected to a reference potential, and the other is connected to a positive voltage source or a negative voltage source. The reference potential may be a ground potential, or may be a prescribed bias potential.

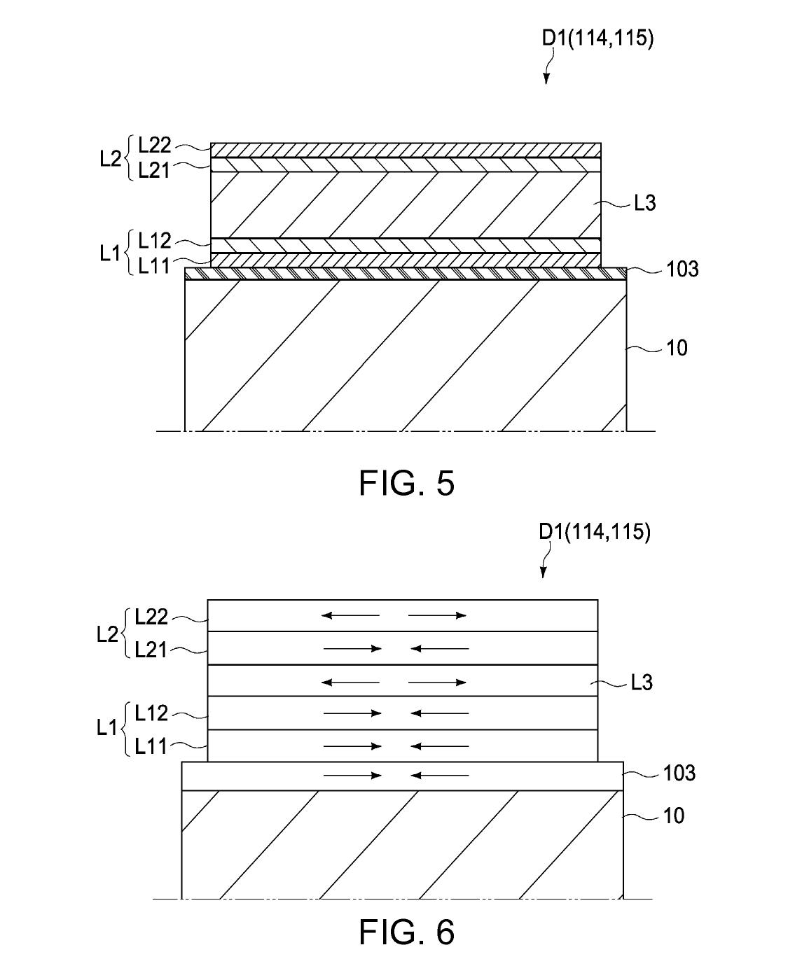

The first and second piezoelectric actuating parts 114, 115 have the same configuration, and in this embodiment, each piezoelectric actuating part is made of a piezoelectric element D1 having a cross-sectional structure shown in FIG. 5. The piezoelectric element D1 is formed by depositing a lower metal layer L11, a lower conductive oxide layer L12, a piezoelectric layer L3, an upper conductive oxide layer L21, and an upper metal layer L22 in this order on the insulating film 103. The lower electrode layer L1 of the piezoelectric element D1 corresponds to the stack of the lower metal layer L11 and the lower conductive oxide layer L12. The upper electrode layer L2 corresponds to the stack of the upper conductive oxide layer L21 and the upper metal layer L22.

There is no special limitation on materials for forming the lower metal layer L11 and the upper metal layer L22, and in this embodiment, each layer is constituted of a Ti film as an adhesion layer and a Pt film deposited thereon. The thickness of the lower metal layer L11 is about 0.2 μm, for example, and the thickness of the upper metal layer L22 is about 0.1 μm, for example.

There is no special limitation on the material for forming the lower conductive oxide layer L12 and the upper conductive oxide layer L21, and in this embodiment, each layer is made of LNO (LaNiO₃: lanthanum nickelate). There is no special limitation on the thickness of each layer, and it can be set to 0.18 μm, for example. In this embodiment, the upper conductive oxide layer L21 and the upper metal layer L22 function as a stress control layer that controls the internal stress of the piezoelectric element D1. With this layer, the internal stress of the piezoelectric element D1 remains constant.

In this embodiment, the piezoelectric layer L3 is formed of PZT (lead zirconate titanate) in a thickness of about 1.5 μm. The composition ratio of PZT may be the stoichiometric composition ratio, or a composition ratio with a lower degree of oxidation than that of the stoichiometric composition ratio. The thickness of the piezoelectric layer L3 is not limited to a specific value, and may be appropriately set in accordance with the material, piezoelectric properties to be obtained, and the like. There is no special limitation on the deposition method of the PZT film, and in this embodiment, the sol-gel method is used. However, a dry process such as sputtering or MOCVD and a wet process such as the liquid phase epitaxy method may be used instead.

Next, the signal line 12 and the ground lines 131, 132 will be explained.

The signal line 12 and the ground lines 131, 132 are respectively formed above the front surface 101 of the base substrate 10 through the insulating film 103. The signal line 12 is electrically connected to a not-shown signal terminal formed on the base substrate 10. The ground lines 131, 132 are electrically connected to not-shown ground terminals formed on the base substrate 10. The signal line 12 is a line that transmits a high-frequency signal in a prescribed wireless communication band. The signal line 12 and the ground lines 131, 132 are formed in parallel with each other along the Y axis direction. The ground lines 131, 132 are disposed on the respective sides of the signal line 12 so as to be symmetric with respect to the signal line 12. This way, a coplanar waveguide CPW that has a GSG (Ground-Signal-Ground) wiring structure is obtained.

The signal line 12 is formed to have a certain line width. The width is not limited to a specific value, and can be set in a range of 20 to 500 μm, for example. In this embodiment, it is set to 180 μm. The signal line 12 has a fixed terminal 120 that bridges the opening 104 of the base substrate 10 in the Y axis direction. The fixed terminal 120 is formed in an arch shape immediately above the moveable part 11 (moveable terminal 113), and faces the moveable terminal 113 in the Z axis direction. In the center of the fixed terminal 120, a pair of terminals 121, 122 facing each other in the Y axis direction are formed.

A space between the pair of terminals 121, 122 is smaller than the width of the moveable terminal 113 along the Y axis direction. Respective ends of the terminals 121, 122 are formed at substantially the same level from the front surface 101 of the base substrate 10. That is, when the moveable terminal 113 is moved toward the fixed terminal 120 of the signal line 12 as a result of actuating the moveable part 11, the moveable terminal 113 makes contact with the pair of terminals 121, 122.

There is no special limitation on the width of the moveable terminal 113 or the size of the space between the terminals 121, 122, and the width can be set in a range of 30 to 300 μm, while the space can be set in a range of 30 to 200 μm, for example. In this embodiment, the width of the moveable terminal 113 is 150 μm, and the space between the terminals 121, 122 is 30 μm.

The ground lines 131, 132 respectively have ground line portions 130 that bridge the opening 104 of the base substrate 10 in the Y axis direction. Each of the ground line portions 130 is formed in an arch shape immediately above the moveable part 11 (first or second piezoelectric actuating part 114, 115). The ground line portions 130 are formed to have a substantially identical shape to each other, and the respective top parts thereof facing the moveable part 11 are made flat, for example.

The ground lines 131, 132 are formed to have a certain line width. The width is not limited to a specific value, and can be set in a range of 100 to 1500 μm, for example. In this embodiment, it is set to 400 μm. There is no special limitation on the dimension of the interval between the signal line 12 and the ground lines 131, 132 that face each other in the X axis direction, and it can be set in a range of 5 to 250 μm, for example. In this embodiment, the interval is set to 80 μm.

The signal line 12 and the ground lines 131, 132 are formed of a metal material that has a low resistance rate, and in this embodiment, Au (gold) is used. There is no special limitation on the thickness of the signal line 12 and the ground lines 131, 132, and in this embodiment, the thickness is about 6 μm.

In this embodiment, the signal line 12 and the pair of ground lines 131, 132 are formed to be coplanar with each other on the front surface 101 of the base substrate 10. The fixed terminal 120 and the ground line portions 130 are formed at the same level from the surface of the moveable part 11 (front substrate 101 of the base substrate 10). In this embodiment, the space between the moveable terminal 113 and the fixed terminal 120 (corresponding to the height H) is set to 6 μm.

The piezoelectric actuator 1 of this embodiment has external connecting terminals that are electrically connected to a not-shown mounting substrate (wiring substrate), for example. The external connecting terminals may be the signal terminals connected to the signal line 12, the ground terminals connected to the ground lines 131, 132, terminal layers T1, T2 of the first and second piezoelectric actuating parts 114, 115, and the like, or may be other terminals that are electrically connected to these terminals. There is no special limitation on the mounting method, and the wire bonding method or the flip chip method may be employed.

The piezoelectric actuator 1 of this embodiment is controlled by a not-shown control circuit. The piezoelectric actuator 1 is electrically connected to the control circuit through a wiring pattern on the mounting substrate, for example. The control circuit may be provided as a special control circuit for the piezoelectric actuator 1, which is constituted of a computer including a driver circuit, for example. Alternatively, the control circuit may be a part of a controller that controls the overall operation of a communication device in which the piezoelectric actuator 1 is provided.

Next, a typical operation of the piezoelectric actuator 1 configured in the manner described above will be explained.

In the piezoelectric actuator 1 of this embodiment, in the switch OFF state shown in FIG. 2, the fixed terminal 120 of the signal line 12 faces the moveable terminal 113 over a space H. That is, the signal line 12 remains open, thereby not allowing for a transmission of signals.

On the other hand, when a prescribed actuation voltage is applied to the first and second piezoelectric actuating parts 114, 115, a driving force that causes the first and second cantilevers 111, 112 to elastically deform in the Z axis direction is generated in the moveable part 11. Due to the deformation of the first and second cantilevers 111, 112, the moveable terminal 113 makes contact with the fixed terminal 120, causing the piezoelectric actuator 1 to transition to the switch ON state shown in FIG. 4 from the switch OFF state shown in FIG. 2. This establishes the transmission state of the signal line 12, thereby allowing the signal to pass through the signal line 12.

In the piezoelectric actuator 1 of this embodiment, the signal line 12 and the ground lines 131, 132 constitute the coplanar waveguide CPW as described above. Therefore, in the switch ON state, a reflection of signals caused by impedance mismatch that occurs in a high-frequency range can be prevented, thereby achieving excellent high-frequency transmission characteristics.

In the piezoelectric actuator of this embodiment, the upper electrode layer L2 of the piezoelectric element D1 that constitutes each of the first and second piezoelectric actuating parts 114, 115 includes the upper conductive oxide layer L21 as shown in FIG. 5. Therefore, it is possible to control the curvature of the first and second cantilevers 111, 112 with ease.

That is, each of the layers formed on the first and second cantilevers 111, 112 has a prescribed internal stress (film stress). The size and direction (tensile or compressive) of the internal stress vary depending on the material, film thickness, film forming conditions, and the like, but the size of deformation or warping of the first and second cantilevers 111, 112 is determined by the total internal stress of the respective layers. FIG. 6 is a schematic diagram showing the directions of the internal stresses of the insulating film 103 and respective layers forming the piezoelectric element D1. The insulating film 103, the lower metal layer L11, the lower conductive oxide layer L12, and the upper conductive oxide layer L21 respectively have in-plane compressive stress. The piezoelectric layer L3 and the upper metal layer L22 respectively have in-plane tensile stress.

Even if the upper electrode layer is made of a metal layer only, the internal stresses of the piezoelectric layer L3 and respective layers lying thereunder can be reduced by the internal stress of the metal layer, and it is still possible to control the curvature of the substrate (cantilever). However, the internal stress of the metal layer may change due to the plastic deformation or creep of the metal layer, causing a change in the stress control amount that was initially set, and as a result, the warping of the substrate may occur. Consequently, in the piezoelectric MEMS switch, the curvature of the cantilever would change due to repetitive motion, causing a distance between the moveable terminal and the fixed terminal to change, and as a result, the switch actuation voltage required for the ON operation would change.

To solve this problem, in this embodiment, the upper electrode layer L2 is provided with the upper conductive oxide layer L21. Because the conductive oxide has covalent bonds or ionic bonds, and therefore produces little plastic deformation, relaxation of the stress is less likely to occur. Thus, even with the repetitive motion in the piezoelectric actuator 1, the as-deposited internal stress (film stress) can be stably maintained for a long period of time. Because this makes it possible to prevent a change in the distance between the moveable terminal 113 and the fixed terminal 120, a change in the switch actuation voltage can be prevented, and as a result, reliable switching operation can be ensured for a long period of time. Also, because the conductive oxide conducts electricity, the voltage applied to the piezoelectric element D1 is not divided, and therefore, it is possible to suppress an increase in the actuation voltage of the piezoelectric element D1.

The internal stress of the upper conductive oxide layer L21 is set such that the curvature of the cantilevers 111, 112 after the piezoelectric element D1 is completed comes within a prescribed range. The size of the internal stress can be adjusted through a film thickness, film forming conditions, and the like. The internal stress of the upper conductive oxide layer L21 can be appropriately set in accordance with the size of the internal stress of the piezoelectric layer L3, the length of the cantilevers 111, 112, the allowable curvature of the cantilevers 111, 112, and the like.

In this embodiment, the upper conductive oxide layer L21 is made of LNO. Because a film made of LNO has an in-plane compressive stress, it is possible to achieve a stress relief layer that can be effectively used for the piezoelectric layer L3 that has an in-plane tensile stress. Also, LNO has the perovskite crystal structure, and the lattice constant thereof is 3.84 \acute{Å}, which is close to the lattice constant of PZT (4.01 \acute{Å}). Therefore, it is possible to form an interface structure that causes little distortion between the upper conductive oxide layer L21 and the piezoelectric layer L3.

Further, in this embodiment, the upper electrode layer L2 includes the upper metal layer L22. The upper metal layer L22 may have in-plane tensile stress or in-plane compressive stress, which is appropriately selected depending on the direction of the internal stress that the film stack presents after the upper conductive oxide layer L21 is deposited. In this embodiment, a metal layer that has an in-plane tensile stress is used as the upper metal layer L22. This makes it possible to reduce a difference in stress between an LNO layer, which is used as the upper conductive oxide layer L21, and the piezoelectric layer L3 lying thereunder, when the internal stress of the LNO layer is larger than that of the piezoelectric layer L3.

The upper metal layer L22 is made of the Pt/Ti film as described above, and is formed by depositing a Ti film and a Pt film in this order by sputtering, for example. The Ti film functions as an adhesion layer for the Pt film. The direction of the internal stress of the Pt/Ti film is determined by the film forming temperature. That is, when the Pt/Ti film is formed at room temperature, the resultant film exhibits in-plane compressive stress, but when the film forming temperature is set higher than a certain temperature, the resultant film exhibits an in-plane tensile stress. This temperature varies depending on the process conditions, but is about 150 to 200° C., for example. The higher the film forming temperature is, the greater the in-plane tensile stress becomes.

In this embodiment, the upper metal layer L22 that has an in-plane tensile stress is provided to mitigate the in-plane compressive stress. As described above, by utilizing a difference in film stress between the upper conductive oxide layer L21 and the upper metal layer L22, the internal stress of the upper electrode layer can be optimized.

One may consider that the as-deposited internal stress of the piezoelectric layer L3 changes due to an effect of the internal stress of the lower electrode layer L1 or of the insulating film 103 lying thereunder. However, the film deposition process and the recrystallization process for the piezoelectric layer L3 are sometimes performed at a high temperature of 700° C. or higher so as to facilitate the formation of the perovskite crystals in the piezoelectric layer L3, thereby improving piezoelectric characteristics. In such a case, depending on the temperature in these processes, the internal stress of the lower electrode layer L1 or the insulating film 103 may be cancelled or eliminated due to the annealing effect. Therefore, in most cases, film forming conditions for the upper electrode layer L2 can be designed based on the intrinsic internal stress of the piezoelectric layer L3.

In the piezoelectric element D1 of this embodiment, the lower electrode layer L1 includes the lower conductive oxide layer L12 made of LNO. As described above, LNO has the perovskite crystal structure, and the lattice constant thereof is close to the lattice constant of PZT that is used to form the piezoelectric layer L3. Therefore, the orientation of the piezoelectric layer L3 is improved, and excellent piezoelectric characteristics are obtained.

### (Method of Manufacturing Piezoelectric Actuator)

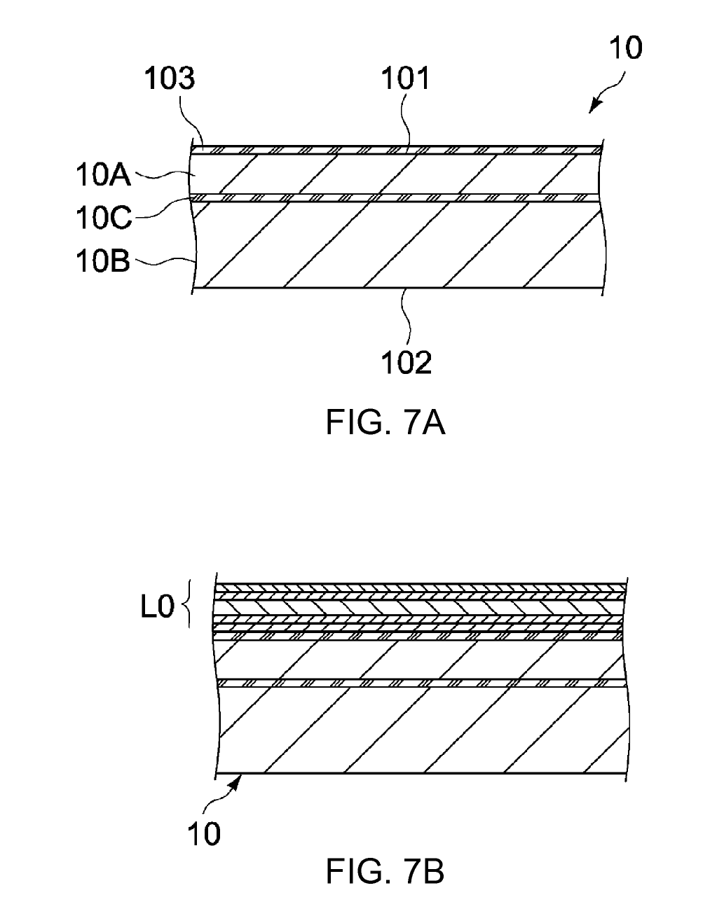

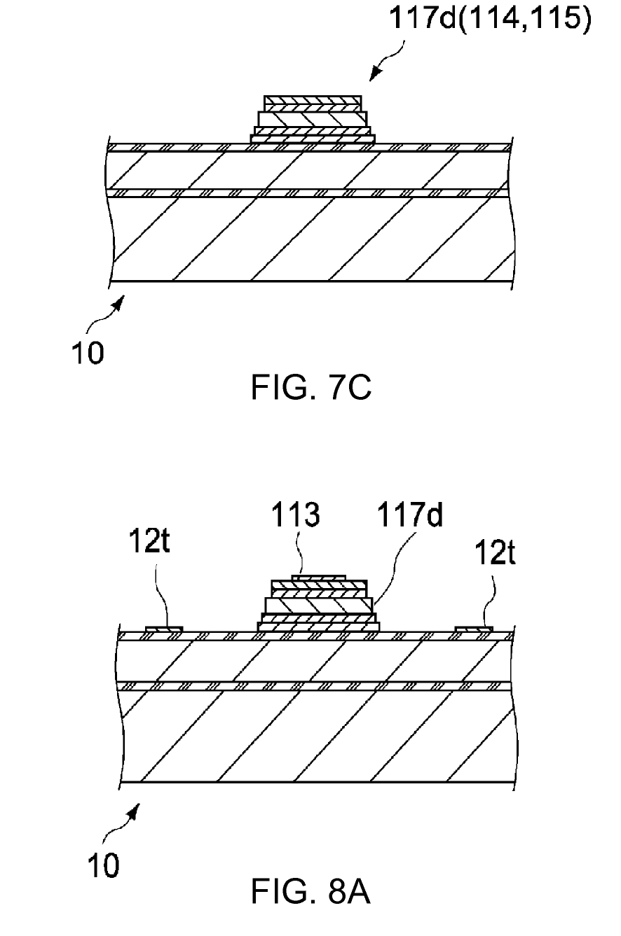

Next, a method of manufacturing the piezoelectric actuator 1 of this embodiment having the above-mentioned configuration will be explained with reference to FIGS. 7A to 9B. FIGS. 7A to 9B are cross-sectional views of the main part of the processes for illustrating the method of manufacturing the piezoelectric actuator 1.

As shown in FIG. 7A, an SOI substrate is prepared as a base substrate 10. The SOI substrate is formed by bonding a first silicon substrate 10A (elastic layer) and a second silicon substrate 10B through a bonding layer 10C. The bonding layer 10C is formed of a silicon oxide film in a thickness of about 1 μm, for example. First, this base substrate 10 is formed as a wafer substrate of a prescribed size, and after forming a plurality of elements (piezoelectric actuators 1) on the wafer substrate simultaneously, the wafer substrate is cut into a prescribed element size by a dicing process.

The base substrate 10 undergoes heat treatment in a thermal oxidation furnace or the like so as to grow a thermal oxide film in a prescribed thickness (0.8 μm, for example) on the entire surfaces thereof including the front surface 101, the rear surface 102, and circumferential faces. In each figure, only the thermal oxide film formed on the front surface 101 of the base substrate 10 is shown (insulating film 103).

Next, as shown in FIGS. 7B and 7C, on the insulating film 103, a film stack L0 that forms the piezoelectric actuating parts 114, 115 and the middle layer 117d is formed. After being formed, the film stack L0 is patterned into prescribed shapes, thereby forming the piezoelectric actuating parts 114, 115 and the middle layer 117d on the first silicon substrate 10A, respectively. The process of forming the film stack L0 will be later described in detail.

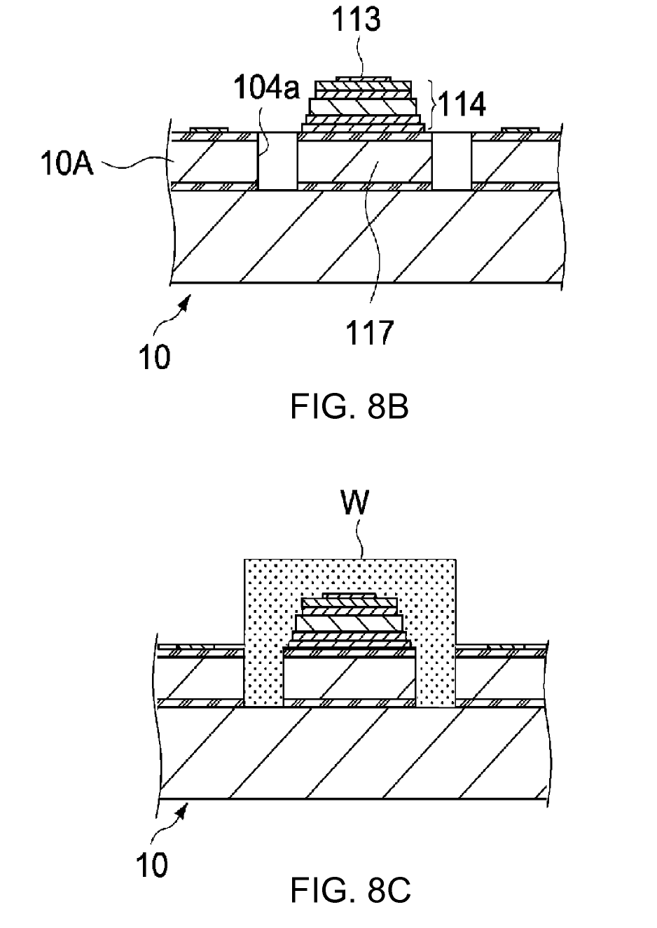

Next, as shown in FIG. 8A, a moveable terminal 113 and signal terminals 12t are formed, respectively. The moveable terminal 113 is formed on the middle layer 117d, and the signal terminals 12t are formed on the surface of the base substrate 10 as a pair between which the middle layer 117d is disposed. The moveable terminal 113 and the signal terminals 12t are respectively made of an about 10 nm-thick Ti film as an adhesion layer and an about 0.2 μm-thick Pt film deposited thereon. The respective films are deposited by sputtering.

Next, as shown in FIG. 8B, a slit 104a is formed so as to penetrate the first silicon substrate 10A in the thickness direction, thereby forming an outline or a profile of the first and second cantilevers 111, 112 and the supporting member 117 (first and second connecting parts 117a, 117b, and supporting part 117c). The slit 104a is formed by forming, on the front surface 101 of the base substrate 10, a resist pattern having an opening that corresponds to a region where the slit 104a is to be formed by a known photolithography technique, and thereafter performing dry-etching using the resist pattern as a mask. At this time, the bonding layer 10C functions as an etching stopper layer of the slit 104a. After forming the slit 104a, the bonding layer 10C on the bottom of the slit 104a is removed by using TMAH (tetramethylammonium hydroxide), for example.

Next, as shown in FIG. 8C, to form a signal line 12 and ground lines 131, 132, a sacrificial layer W is formed on the surface of the base substrate 10. The sacrificial layer W is provided to form respective arch shapes of the fixed terminal 120 and ground line portions 130, and is made of a resist pattern that covers prescribed regions of the moveable terminal 113 and the piezoelectric actuating parts 114, 115.

After forming the sacrificial layer W, the signal line 12 and the ground lines 131, 132 are respectively formed. The signal line 12 and the ground lines 131, 132 are mainly made of an Au plating layer deposited on the sacrificial layer W, and are formed by patterning the Au plating layer into prescribed shapes. Here, a method of depositing the Au plating layer will be explained using an example of a process of forming the signal line 12.

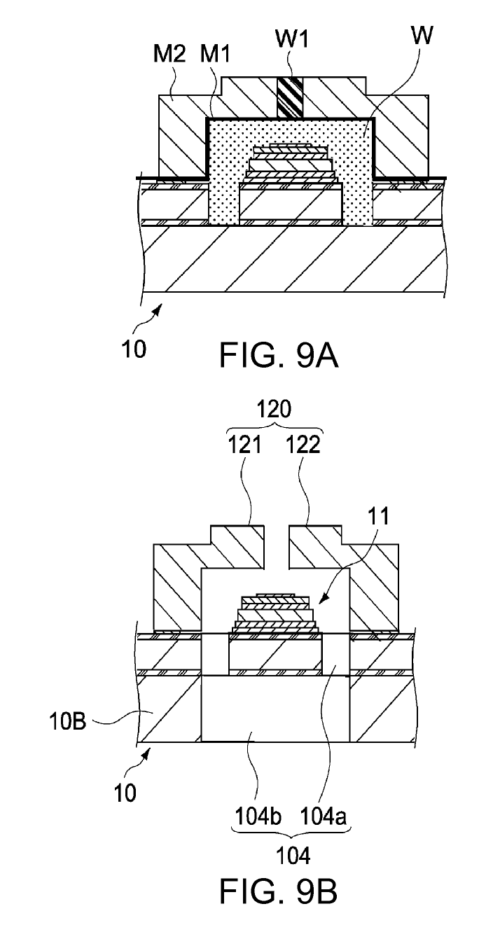

After forming the sacrifice layer W, as shown in FIG. 9A, a seed layer M1, which is an Au plating layer, is deposited on the surface of the base substrate 10 that includes the sacrifice layer W. In this embodiment, the seed layer M1 is made of an about 5 nm-thick Ti film as an adhesion layer and an about 200 nm-thick Au film deposited thereon. The respective films are deposited by sputtering. Next, on the seed layer M1, an Au plating layer M2 is deposited. Here, on the sacrifice layer W that covers the moveable terminal 113, a resist pattern W1 for forming the terminals 121, 122 of the fixed terminal 120 is formed. In this embodiment, the thickness of the Au plating layer M2 is about 6 μm. By patterning the seed layer M1 and the plating layer M2 by wet-etching or dry-etching, the signal line 12 and the ground lines 131, 132 are formed of the stack of the seed layer M1 and the plating layer M2.

Next, as shown in FIG. 9B, a recess 104b is formed in the second silicon substrate 10B so as to be connected to the slit 104a, thereby forming the opening 104 in the base substrate 10 for housing the moveable part 11. In this embodiment, the recess 104b is formed by performing a dry-etching process to the second silicon substrate 10B. After forming the recess 104b, the sacrificial layer W and the resist pattern W1 are removed. The sacrificial layer W is removed by soaking the base substrate 10 in a removal solution so as to dissolve the sacrificial layer W out through the opening 104.

In the manner described above, the piezoelectric actuator 1 of this embodiment is manufactured. According to this embodiment, the moveable part 11 is formed by processing the surface of the base substrate 10 by the semiconductor processing technology, and therefore, it is possible to manufacture a very small piezoelectric actuator with a high degree of accuracy.

Next, a method of forming the piezoelectric element D1 that constitutes the piezoelectric actuating parts 114, 115 (and the middle layer 117d) will be explained.

The piezoelectric element D1 is formed by depositing the lower electrode layer L1, the piezoelectric layer L3, and the upper electrode layer L2 in this order on the insulating film 103 on the surface of the base substrate 10. A process of forming the lower electrode layer L1 includes a process of forming the lower metal layer L11 and a process of forming the lower conductive oxide layer L12.

### (Process of Forming Lower Electrode Layer)

The lower metal layer L11 is made of a Ti film as an adhesion layer and a Pt film deposited thereon. There is no special limitation on the respective thicknesses, but in this embodiment, the Ti layer is 10 nm thick, and the Pt layer is 180 nm thick. The Ti layer and the Pt layer are deposited by a DC sputtering method at a temperature of 100° C. The film forming pressure and sputtering power are not limited to specific values, and for example, can be set in a range of 0.1 to 1 Pa and in a range of 100 to 500 W, respectively. When the lower metal layer L11 is formed at room temperature, the resultant layer has an in-plane compressive stress. A single layer of the lower metal layer L11 formed under the above-mentioned conditions has an in-plane compressive stress of about 200 MPa, but it is estimated that the stress will be reduced to a certain extent as a result of the heat application in the subsequent process of forming the piezoelectric layer L3.

Next, as the lower conductive oxide layer L12, an LNO (lanthanum nickelate) film is deposited by the RF sputtering method. The thickness of the lower conductive oxide layer L12 is about 0.18 μm, and the film forming temperature is 300° C. There is no special limitation on the film forming conditions, and the film forming pressure can be set in a range of 0.1 to 1 Pa, and the RF power can be set in a range of 100 to 500 W, for example. A single layer of the lower conductive oxide layer L12 formed under the above-mentioned conditions has an in-plane compressive stress of about 1000 MPa, but it is estimated that the stress will be reduced to a certain extent as a result of the heat application in the subsequent process of forming the piezoelectric layer L3.

### (Process of Forming Piezoelectric Layer)

Subsequently, the piezoelectric layer L3 is formed on the lower conductive oxide layer L12. In this embodiment, as the piezoelectric layer L3, a PZT (lead zirconate titanate) film is deposited by the sol-gel method. There is no special limitation on the thickness, and in this embodiment, the thickness is set to be 1.5 μm. The film forming temperature can be set in a range of 550 to 700° C., and is set to 600° C. in this embodiment. A single layer of the piezoelectric layer L3 formed under the above-mentioned conditions has an in-plane tensile stress of about 200 to 300 MPa, but it is estimated that the stress will be reduced to at least about 100 MPa as a result of the heat application in the subsequent process of forming the upper electrode layer L2.

According to this embodiment, because the underlying layer of the piezoelectric layer L3 is the lower conductive oxide layer L12 (LNO layer) that has the perovskite structure in the same manner as the piezoelectric layer L3, the crystal orientation of the piezoelectric layer L3 is improved, achieving excellent piezoelectric characteristics.

The piezoelectric layer L3 may undergo a recrystallization process after the film deposition. This makes it possible to facilitate the formation of the perovskite crystal structure in the piezoelectric layer L3, thereby improving the piezoelectric characteristics. The recrystallization temperature can be set in a range of 550 to 700° C., for example.

### (Formation of Upper Electrode Layer)

Next, the upper conductive oxide layer L21 is formed. In this embodiment, as the upper conductive oxide layer L21, LNO (lanthanum nickelate) was deposited by the RF sputtering method. There is no special limitation on the thickness of the upper conductive oxide layer L21, but the greater the thickness is, the larger the internal stress becomes. The thickness of the upper conductive oxide layer L21 is set to adjust the film stress such that the curvature of the cantilevers 111, 112 do not exceed a prescribed range (1 μm or less, for example) after the moveable part 11 is formed in the above-mentioned process, for example. In this embodiment, the thickness is set to about 0.18 μm. There is no special limitation on the film forming conditions, and for example, the film forming temperature can be set to 300° C., the film forming pressure can be set in a range of 0.1 to 1 Pa, and the RF power can be set in a range of 100 to 500 W. A single layer of the upper conductive oxide layer L21 formed under the above-mentioned conditions has an in-plane compressive stress of about 1000 MPa, but due to heat applied in the subsequent process of forming the upper metal layer L22, the stress will be reduced to at least about 480 MPa.

On the upper conductive oxide layer L21, the upper metal layer L22 is formed. In this embodiment, the upper metal layer L22 is made of a Ti film as an adhesion layer and a Pt film deposited thereon. There is no special limitation on the thickness of the films, and in this embodiment, the thickness of the Ti layer is 10 nm, and the thickness of the Pt layer is 80 nm. The Ti layer and the Pt layer are deposited by the DC sputtering method at a temperature of 300° C. By being formed at a temperature of 200° C. or higher, the upper metal layer L22 exhibits an in-plane tensile stress. The film forming pressure and the sputtering power are not limited to specific values, and, for example, can be set in a range of 0.1 to 1 Pa and in a range of 100 to 300 W, respectively. It is estimated that a single layer of the upper metal layer L22 formed under the above-mentioned conditions has an in-plane tensile stress of about 400 MPa.

By forming the upper metal layer L22 such that the resultant layer exhibits an in-plane tensile stress, the internal stress of the upper conductive oxide layer L21 is mitigated. This is an effective technique to be used when the size of internal stress of the upper conductive oxide layer L21 and the size of internal stress of the piezoelectric layer L3 largely differ from each other as described above. By utilizing the difference in film stress between the upper conductive oxide layer L21 and the upper metal layer L22 in the above manner, the internal stress of the upper electrode L2 can be optimized.

The size of the internal stress of the upper metal layer L22 can be determined in accordance with the internal stress of the upper conductive oxide layer L21. The internal stress of the upper metal layer L22 may be set by taking into account a change in the internal stress of the upper conductive oxide layer L21 as a result of the heat application in a process of forming the upper metal layer L22.

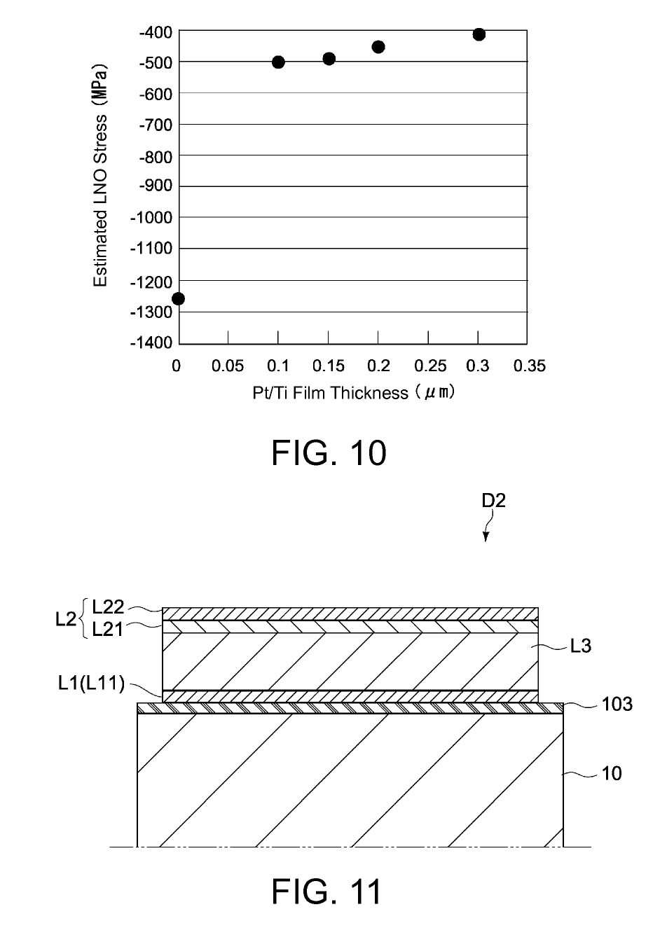

FIG. 10 shows an example of a relationship between the thickness of the upper metal layer (Pt/Ti) L22 and the internal stress of the upper conductive oxide layer (LNO) L21. The thickness of the upper conductive oxide layer L21 was set to 0.188 μm, and the internal stress of LNO was estimated based on the curvature of the substrate. As shown in FIG. 10, the internal stress of the LNO single layer was an in-plane compressive stress of 1200 to 1300 MPa, but as shown in the figure, when the Pt/Ti layer is deposited thereon, the stress was reduced to around 400 to 500 MPa, depending on the thickness of the Pt/Ti layer. In this embodiment, the upper metal layer L22 was formed such that the size of the internal stress of the entire upper electrode layer L2 is about 480 MPa.

In the manner described above, the film stack L0 constituting the piezoelectric element D1 is formed. Thereafter, by pattering the film stack into prescribed shapes, the piezoelectric actuating parts 114, 115 and the middle layer 117d are formed, respectively. The patterning of the respective layers does not necessarily have to be performed after completing the film stack L0, but may be performed after each layer is deposited.

According to this embodiment, the internal stress of the piezoelectric element D1 is controlled by the film stress of the upper electrode layer L2, and therefore, it is possible to adjust the internal stress of the piezoelectric element D1 in the final step of the process of forming the piezoelectric element D1. Also, in this embodiment, because the piezoelectric element D1 does not undergo a process that is performed at a temperature over 300° C., the internal stress of the upper electrode layer L2 is not relaxed in the subsequent processes, and the prescribed internal stress (480 MPa) can be maintained. This makes it possible to effectively prevent the internal stress of the piezoelectric layer L3 from causing the cantilevers 111, 112 to warp. As a result, the distance (H) between the moveable terminal 113 and the fixed terminal 120 can be set with a high degree of accuracy, and a highly-reliable piezoelectric actuator can be manufactured in a stable manner.

The upper metal layer L22 is deposited at a temperature of 200° C. or higher. Therefore, the internal stress of the upper electrode layer L2 is not relaxed by the heat applied in the reflow soldering, which is performed for mounting the completed element on a wiring substrate.

According to this embodiment, the upper electrode layer L2 includes the conductive oxide layer L21, and therefore, unlike a metal material, stress relaxation due to plastic deformation, creep, or the like does not occur. As a result, it is possible to suppress the stress relaxation of the upper electrode layer L2 caused by repetitive motion in the piezoelectric actuator 1, allowing a stable switching operation to be maintained for a long period of time.

### Embodiment 2

FIG. 11 is a schematic cross-sectional view that shows a configuration of a piezoelectric actuating part of a piezoelectric actuator according to Embodiment 2 of the present invention. In this embodiment, descriptions of configurations and operations that are similar to those of Embodiment 1 are omitted or abridged, and differences from Embodiment 1 will be mainly described.

The piezoelectric actuating part of the piezoelectric actuator of this embodiment is constituted of a piezoelectric element D2 shown in FIG. 11. The piezoelectric element D2 differs from Embodiment 1 above in that the lower electrode layer L1 is made of the lower metal layer L11 only. Even with this configuration, the stress of the entire piezoelectric element D2 can be controlled by the upper electrode layer L2. As an example, when the upper conductive oxide layer L21 was made of LNO in a thickness of 0.15 μm, and the upper metal layer L22 was made of a Pt/Ti layer in a thickness of 0.33 μm, the upper electrode layer L2 having an in-plane compressive stress of about 330 MPa was obtained.

Embodiments of the present invention were described above, but the present invention is not limited to the above embodiments, and it is apparent that various modifications can be made without departing from the scope of the present invention.

For example, in the above embodiments, LaNiO₃ (LNO) was used as the material of the lower conductive oxide layer L12 and the upper conductive oxide layer L21. However, alternatively, other oxide materials made of two elements or three or more elements such as SrRuO₃, SrTiO₃, LaAlO₃, YAIO₃, and HfO₂ may be used as the conductive oxide. The conductive oxide material does not necessarily have to have an in-plane compressive stress as described above, and may be a material that has an in-plane tensile stress. The material can be appropriately selected in accordance with the direction of the internal stress of the piezoelectric layer.

In the above embodiments, the piezoelectric layer L3 was made of lead zirconate titanate (PZT), but the piezoelectric layer L3 may be made of other piezoelectric materials such as potassium sodium niobate, lithium niobate, lithium tantalate, and aluminum nitride.

In the above embodiments, the upper electrode layer of the piezoelectric element was made of a film stack of a conducive oxide layer and a metal layer, but the upper electrode layer may be formed of a conductive oxide layer only. Each of the metal layers in the upper and lower electrode layers was made of a Pt/Ti film, but may be made of a single metal layer such as a Ta layer, for example.

In the above embodiments, an MEMS switch in which two cantilevers constitute a moveable part was described as an example of the piezoelectric actuator, but the present invention can also be applied to an MEMS switch in which a moveable part is constituted of a single cantilever. In addition to the MEMS switch, the present invention can also be applied to other piezoelectric actuators in which a cantilever such as a probe of an atomic force microscope (AFM), an accelerometer, or gyroscope is actuated by a piezoelectric element (or in which stress acting on a cantilever is detected by a piezoelectric element).

In the above embodiments, a piezoelectric switch was described as an example of the piezoelectric actuator, but the present invention can also be applied to other piezoelectric actuators having a piezoelectric actuating part such as a variable capacitor and a variable filter obtained by combining a variable capacitor and a switch. The piezoelectric actuator according to the present invention can be used as a high-frequency switch, a high-frequency filter, or the like built in a wireless communication terminal such as a mobile phone.

It will be apparent to those skilled in the art that various modification and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A piezoelectric actuator, comprising:
a base substrate that includes a base and a cantilever having a first end portion fixed to the base; and
a piezoelectric element that can elastically deform the cantilever, the piezoelectric element having a first electrode formed on the cantilever, a piezoelectric layer formed on the first electrode, and a second electrode including a first conductive oxide layer formed on the piezoelectric layer.

2. The piezoelectric actuator according to claim 1,
wherein the piezoelectric layer is made of a material that has an in-plane tensile stress, and
wherein the first conductive oxide layer is made of a material that has an in-plane compressive stress.

3. The piezoelectric actuator according to claim 2,
wherein the piezoelectric layer is made of lead zirconate titanate, and
wherein the first conductive oxide layer is made of LaNiO₃.

4. The piezoelectric actuator according to claim 2,
wherein the second electrode further comprises a metal layer formed on the first conductive oxide layer, the metal layer having an in-plane tensile stress.

5. The piezoelectric actuator according to claim 4,
wherein the metal layer comprises: a Ti film as an adhesion film; and a Pt film deposited thereon.

6. The piezoelectric actuator according to claim 2,
wherein the first electrode includes a second conductive oxide layer.

7. The piezoelectric actuator according to claim 6,
wherein the second conductive oxide layer is made of LaNiO₃.

8. The piezoelectric actuator according to claim 1,
wherein the second electrode is formed to be thinner than the first electrode.

9. The piezoelectric actuator according to claim 1,
wherein the cantilever has a second end portion on a side opposite to the first end portion, and
wherein the piezoelectric actuator further comprises:
a moveable terminal connected to the second end portion; and
a signal line that is connected to the base, the signal line having a fixed terminal that can make contact with the moveable terminal when the cantilever is actuated by the piezoelectric element and deformed.

10. A method of manufacturing a piezoelectric actuator, comprising:
forming a first electrode on a base substrate in a region where a cantilever is to be formed;
forming, on the first electrode, a piezoelectric layer that is made of a material that has an in-plane tensile stress;
forming, on the piezoelectric layer, a second electrode that includes a conductive oxide layer having an in-plane compressive stress; and
forming the cantilever by etching the base substrate.

11. The method of manufacturing a piezoelectric actuator according to claim 10,
wherein the step of forming the second electrode comprises:
forming the conductive oxide layer on the piezoelectric layer; and
forming, on the conductive oxide layer, a metal layer that has an in-plane tensile stress.

12. The method of manufacturing a piezoelectric actuator according to claim 11,
wherein a temperature at which the metal layer is deposited is 200° C. or higher.

13. A wireless communication terminal comprising the piezoelectric actuator according to claim 1.
